(19) United States
(12) Patent Application Publication
(10) Pub. No.: US 2016/0288272 A1
(43) Pub. Date: Oct. 6, 2016

(54) COATED WIRE FOR BONDING APPLICATIONS

(71) Applicant: HERAEUS DEUTSCHLAND GMBH & CO. KG, Hanau (DE)

(72) Inventors: Annette LUKAS, Rodenbach (DE); Patrick WENZEL, Alzenau (DE); Michael DEUSCHLE, Rosbach (DE); Eugen MILKE, Nidderau (DE); Sven THOMAS, Frankfurt (DE); Jürgen SCHARF, Mömbris (DE)

(21) Appl. No.: 15/038,177

(22) PCT Filed: Nov. 21, 2013
(86) PCT No.: PCT/EP2013/074391

§ 371 Date: May 20, 2016

(51) Int. Cl. B23K 35/40; B23K 35/02; H01L 23/00; B23K 35/32; C23F 17/00; C23C 18/08; B23K 35/30

(52) U.S. Cl. CPC B23K 35/40; C23C 18/08; B23K 35/0272; B23K 35/302; B23K 35/322; C23F 17/00; H01L 24/45; H01L 24/43; H01L 24/745; H01L 24/85; H01L 24/48; C22F 1/08

(57) ABSTRACT

A bonding wire according to the invention contains a core having a surface and a coating layer which is at least partially superimposed over the surface of the core. The core contains a core main component selected from copper and silver and the coating layer contains a coating component selected from palladium, platinum, gold, rhodium, ruthenium, osmium and iridium. The coating layer is applied on the surface of the core by depositing a film of a liquid containing a coating component precursor onto a wire core precursor and heating the deposited film to decompose the coating component precursor into a metallic phase.

### CROSS-REFERENCE TO RELATED APPLICATIONS

This application is a Section 371 of International Application No. PCT/EP2013/074391, filed Nov. 21, 2013, which was published in the English language on May 28, 2015 under International Publication No. WO 2015/074703 A1, and the disclosure of which is incorporated herein by reference.

### BACKGROUND OF THE INVENTION

Bonding wires are used in the manufacture of semiconductor devices for electrically interconnecting an integrated circuit and a printed circuit board during semiconductor device fabrication. Further, bonding wires are used in power electronic applications to electrically connect transistors, diodes and the like with pads or pins of the housing. While bonding wires were originally made from gold, nowadays less expensive materials, such as copper, are used. While copper wire provides very good electric and thermal conductivity, wedge-bonding of copper wire has its challenges. Moreover, copper wires are susceptible to oxidation of the wire.

It is understood that bonding wires are specific items which are defined by their suitability to be used in ball-bonding and/or wedge bonding machines. This is usually not the case for ordinary wires. On the other hand, a bonding wire could be well used for standard purposes of ordinary wires.

With respect to wire geometry, most common are bonding wires of circular cross-section and bonding ribbons, which have a more or less rectangular cross-section. Both types of wire geometries have their advantages, making them useful for specific applications. Thus, both types of geometries have their share in the market. For example, bonding ribbons have a larger contact area for a given cross-sectional area. However, bending of the ribbons is limited and orientation of the ribbon must be observed when bonding in order to arrive at acceptable electrical contact between the ribbon and the element to which it is bonded. Turning to bonding wires, these are more flexible to bending. However, bonding involves either soldering or larger deformation of the wire in the bonding process, which can cause harm or even destroy the bonding pad and underlying electric structures of the element which is bonded thereto.

Some recent developments were directed to bonding wires having a copper core and a protective coating layer. As a core material, copper is chosen because of high electric conductivity. With regard to the coating layer, palladium is one of the possible choices. These coated bonding wires combine the advantages of the copper wire with less sensitivity to oxidation. Nevertheless, there is an ongoing need for further improving bonding wire technology with regard to the bonding wire itself and the bonding processes.

### BRIEF SUMMARY OF THE INVENTION

The invention is related to a bonding wire comprising a core having a surface and a coating layer which is at least partially superimposed over the surface of the core. The core comprises a core main component selected from the group consisting of copper and silver and the coating layer comprises a coating component selected from the group consisting of palladium, platinum, gold, rhodium, ruthenium, osmium and iridium. The coating layer is applied on the surface of the core by depositing a film of a liquid containing a coating component precursor onto a wire core precursor, and heating the deposited film to decompose the coating component precursor into a metallic phase.

The invention further relates to a system for bonding an electronic device, comprising a first bonding pad, a second bonding pad and a wire according to the invention, wherein the inventive wire is connected to at least one of the bonding pads by wedge-bonding.

The invention further relates to a method for manufacturing a bonding wire, comprising the steps of:

a. providing a wire core precursor with copper or silver as a core main component; and

b. depositing a material to form a layer on the core precursor. The deposited material comprises a coating component selected from palladium, platinum, gold, rhodium, ruthenium, osmium and iridium and step b is performed by depositing a film of a liquid containing a coating component precursor onto the wire core precursor and heating the deposited film to decompose the coating component precursor into a metallic phase.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic of a wire according to an embodiment of the invention;

FIG. 2 is a cross sectional view of the wire of FIG. 1;

FIG. 3 is a flow chart of a process for manufacturing a wire according to an embodiment of the invention;

FIG. 4 is a schematic of an electric device containing a wire according to an embodiment of the invention;

FIG. 5 is a schematic of wire coating equipment according to an embodiment of the invention;

FIG. 6 shows an Auger depth profile of a first inventive wire; and

FIG. 7 shows an Auger depth profile of a second inventive wire.

### DETAILED DESCRIPTION OF THE INVENTION

It is an object of the invention to provide improved bonding wires.

It is another object of the invention to provide a bonding wire which has good processing properties and which has no specific needs when interconnecting, thus saving costs.

It is also an object of the invention to provide a bonding wire which has excellent electrical and thermal conductivity.

It is a further object of the invention to provide a bonding wire which exhibits improved reliability.

It is a further object of the invention to provide a bonding wire which exhibits excellent bondability, in particular with respect to the forming of a free air ball (FAB) in the course of a ball bonding procedure.

It is another object of the invention to provide a bonding wire which shows good bondability with respect to a wedge bonding and/or second bonding.

It is another object of the invention to provide a bonding wire which has improved resistance to corrosion and/or oxidation.

It is another object to provide a system for bonding an electronic device, to be used with standard chip and bonding technology, which system shows reduced failure rate at least with respect to a first bonding.

It is another object to provide a method for manufacturing an inventive bonding wire which basically showing no increase in manufacturing costs compared with known methods.

Surprisingly, wires of the present invention have been found to solve at least one of the objects mentioned above. Further, several alternative processes for manufacturing these wires have been found which overcome at least one of the challenges of manufacturing wires. Further, systems comprising the wires of the invention were found to be more reliable at the interface between the wire according to the invention and other electrical elements, e.g., a printed circuit board, a pad/pin etc.

A first aspect of the invention is a bonding wire comprising a core having a surface and a coating layer which is at least partially superimposed over the surface of the core. The core comprises a core main component selected from the group consisting of copper and silver and the coating layer comprises a coating component selected from the group consisting of palladium, platinum, gold, rhodium, ruthenium, osmium and iridium. The coating layer is applied on the surface of the wire core by depositing a film of a liquid containing a coating component precursor onto a wire core precursor, and heating the deposited film to decompose the coating component precursor into a metallic phase.

More preferred embodiments have one of the combinations of a core main component and a coating component as follows:

| Core main component | Coating component |
|---|---|
| Cu | Pd |
| Cu | Pt |
| Ag | Au |
| Ag | Pd |
| Ag | Pt |

Such wires according to the invention have an optimized coating layer with respect to cost of production and effectiveness. It has surprisingly turned out that there are no relevant drawbacks of corrosion resistance or other properties if the coating layer does not consist of the pure coating component, but has significant shares of the core main component.

For the present application, the term bonding wire comprises all shapes of cross-sections and all usual wire diameters, though bonding wires with circular cross-section and thin diameters are preferred.

If no other specific definition is provided, all contents or shares of components are presently given as shares in mole-%. In particular, shares given in percent are understood as mole-%, and shares given in ppm (parts per million) are understood as mole-ppm.

In case of the present invention, Auger Depth Profiling is chosen as the method of defining the composition of the coating layer. In this method, the elemental composition is measured by Auger analysis on a respective surface of the wire. A composition of the coating layer in different depths with respect to a surface of the coating layer is measured by sputter depth profiling. While the coating layer is sputtered by an ion beam at a defined rate, the composition is followed by accompanying Auger analysis.

The amounts of the core main component and/or the coating component in the coating layer are understood as averaged over the entire volume of the coating layer, if no other specification is given.

An interface region of the coating layer and the wire core is usually present, as in all real systems of layered structures. Such an interface region can be more or less narrow, depending on the wire manufacturing method and further parameters. For the purpose of clarity hereinafter, a border of the coating layer and/or the wire core is usually defined as a given percentage drop of a component signal in a depth profiling measurement.

The term “superimposed” in the context of this invention is used to describe the relative position of a first item, e.g., a copper core, with respect to a second item, e.g., a coating layer. Possibly, further items, such as an intermediate layer, might be arranged between the first and the second item. Preferably, the second item is at least partially superimposed over the first item, e.g., for at least 30%, 50%, 70% or for at least 90% with respect to the total surface of the first item. Most preferably, the second item is completely superimposed over the first item. Generally preferred, the coating layer is an outermost layer of the bonding wire. In other embodiments, the coating layer can be superimposed by a further layer.

The wire is a bonding wire in particular for bonding in microelectronics. The wire is preferably a one-piece object.

A component is a “main component” if the share of this component exceeds all further components of a referenced material. Preferably, a main component comprises at least 50% of the total weight of the material.

The core of the wire preferably comprises copper or silver in an amount of at least 90%, respectively, more preferably at least 95%. In other embodiments, copper and silver can be simultaneously present, wherein one of the two elements provides for the core main component. In a most preferred embodiment of the invention, the wire core consists of pure copper, wherein a sum of other components than copper is less than 0.1%.

In the case of an alternative advantageous embodiment of the invention, the core main component is copper and can comprise small amounts of palladium, in particular less than 5%, as a component. More preferably, the amount of palladium in the core is between 0.5% and 2%, most preferably between 1.1% and 1.8%. In such a case, the sum of other components than copper and palladium is preferably less than 0.1%.

Generally preferred are embodiments wherein the coating layer has a thickness of less than 0.5 μm. If the coating layer is sufficiently thin, possible effects of the coating layer in the bonding process are reduced. The term “thickness” in the context of this invention is used to define the size of a layer in a perpendicular direction to the longitudinal axis of the wire core, which layer is at least partially superimposed over the surface of the wire core.

The present invention is particularly related to thin bonding wires. The observed effects are specifically beneficial to thin wires, for example because of the sensitivity to oxidation of such wires. In the present case, the term “thin wire” is defined as a wire having a diameter in the range of 8 μm to 80 μm. Most preferably, a thin bonding wire according to the invention has a thickness in the range of 12 μm to 50 μm.

Such thin wires mostly, but not necessarily, have a cross-sectional view essentially in the shape of a circle. The term “a cross-sectional view” in the present context refers to a view of a cut through the wire, wherein the plane of the cut is perpendicular to the longitudinal extension of the wire. The cross-sectional view can be found at any position on the longitudinal extension of the wire. A “longest path” through the wire in a cross-section is the longest chord which can be laid through the cross-section of the wire within the plane of the cross-sectional view. A “shortest path” through the wire in a cross-section is the longest chord perpendicular to the longest path within the plane of the cross-sectional view defined above. If the wire has a perfect circular cross-section, then the longest path and the shortest path become indistinguishable and share the same value. The term “diameter” is the arithmetic mean of all geometric diameters of any plane and in any direction, wherein all planes are perpendicular to the longitudinal extension of the wire.

Generally preferred, the thickness of the coating layer roughly scales with the wire diameter at least within certain ranges. At least in the case of thin wires, a total thickness of the coating layer is preferably between about 0.3% and 0.6% of the wire diameter.

In particular embodiments, a large amount of the core main component might also extend to the outer surface of the coating layer, but other embodiments might provide that the very outermost part of the coating layer predominantly contains further substances like carbon or oxygen.

In yet further embodiments, the outermost surface of the coating layer may be covered with a few monolayers of a noble metal like gold or platinum, or even with a mixture of noble metals. In a specifically preferred embodiment of the invention, the coating layer is covered with a top layer of a thickness between 1 nm and 100 nm. Preferably, the thickness of the top layer is between 1 nm and 50 nm, and most preferably between 1 nm and 25 nm. Such a top layer preferably consists of a noble metal or an alloy of one or more noble metals. Preferred noble metals are selected from the group consisting of gold, silver and their alloys.

Generally advantageously, an outer surface range of the coating layer contains carbon as a main component. The carbon can be present as elemental carbon or as an organic substance. Generally, such an outer surface range has a thickness of just a few monolayers, in particular less than 5 nm.

In a preferred embodiment of the invention, the film of the liquid is applied after the wire core has been drawn to a final diameter. This ensures that the deposited material keeps its original grain structure and particularly allows for highly isotropic grains. Such a grain structure can help with good free air ball formation. Furthermore, the deposited layer cannot have negative effects on the drawing procedure, like increased wear of the drawings dies.

Generally preferred, the film of the liquid is applied onto a surface which is freshly generated in the course of drawing the wire. Generating a fresh surface means that the surface has not been exposed to a reactive environment (air, oxygen, etc.) for more than a minute, in particular for less than a second. Generating such a fresh surface can be achieved by mechanical means like drawing the wire through a drawing die. Alternatively, the fresh surface can be generated by other means like, e.g., chemical etching. By applying the liquid onto the wire during or immediately after drawing the wire through a drawing die, the buildup of oxides and/or the adsorption of contaminants are effectively prevented.

In a most preferred embodiment of the invention, the film of the liquid is applied at the position of a drawing die. In such embodiment, the surroundings of an opening of the drawing die could be wetted with a sufficient stream of the liquid, or the drawing die could be submerged in a reservoir filled with the liquid.

For adjusting a thickness of the final coating layer, the thickness of the deposited film can be influenced. This can be achieved by adjusting the concentration of the coating component precursor. As a further measure, the viscosity of the liquid can be adjusted.

Preferably, the liquid is chosen and/or adjusted in the way that it has a dynamic viscosity of more than 0.4 mPa*s at 20° C. More preferably, the viscosity is higher than 1.0 mPa*s, and most preferably higher than 2.0 mPa*s.

One possible way is to use additives influencing the viscosity of the liquid. Such an additive can be, for example, glycerine or any suitable substance with high viscosity.

Alternatively or additionally, a solvent of the coating component precursor can be chosen to have a demanded viscosity. For example, isopropyl alcohol may be chosen as a polar solvent which has a viscosity of more than 2.0 mPa*s (millipascal-second) at room temperature. The choice of the solvent may further be combined with the use of additives depending on the demands.

Further alternatively or additionally, the deposition of the solvent may be performed at a controlled low temperature, in particular below 10° C., in order to provide for a high and/or defined viscosity.

In generally preferred embodiments, the coating component precursor is a substance appearing as a resin, as a wax, or as an oil at standard conditions (20° C., atmospheric pressure). Most preferred is the appearance as a resin or as a wax. It has surprisingly turned out that such substances do not tend to form crystals with the coating component when heated for decomposition. This is advantageous for the buildup of a homogenous and well performing coating layer.

Generally, the coating component can be dissolved in a suitable solvent, in particular an organic solvent. This allows for easy adjustment of the liquid's properties such as its viscosity. A solvent is considered to be a volatile part of the liquid which will largely evaporate when heating the liquid, and which is not adding to carbon-containing residues on or in the coated wire.

If the coating component precursor is a substance appearing as a resin, as a wax, or as an oil, it is particularly preferred for the liquid to comprise only the precursor and a solvent or a mixture of solvents. This prevents unwanted residues of non-volatile additives on the wire.

In a generally preferred embodiment of the invention, the coating component precursor comprises a salt of a branched carboxylic acid. It has turned out that the branching of the carboxylic acid supports non-crystalline properties of the salt and can improve the properties of the coating layer. Further, salts of branched carboxylic acids tend to show a high viscosity and/or the demanded viscosity can be easily adjusted by adding a solvent.

Even more preferred, the coating component precursor comprises a salt of a secondary carboxylic acid or a tertiary carboxylic acid.

This means that the branching starts at the first carbon atom of the functional group and hence allows for the demanded properties while a small total number of C-atoms is needed.

Such carboxylic acids are sometimes referred to as “Koch-acids” or as acids manufactured by the “Koch-reaction.”

Even more preferred, the carboxylic acid is a saturated acid, allowing for a good stability against oxidation.

In particularly preferred embodiments, the carboxylic acid is selected from the group consisting of
a. dimethylpropionic acid (pivalic acid),
b. dimethylbutyric acid, and
c. dimethylpentanoic acid,
or at least two thereof.

These specific acids have turned out to show particularly advantageous properties in the above mentioned sense. It is particularly preferred that the organic part of the coating component precursor contains at least 30% of one or more of these acids. The most preferred choice is pivalic acid. It is preferred that the organic part of the coating component precursor contains at least 30% of pivalic acid.

In order to keep the amount of residual carbon in the wire low, the number of carbon atoms of the carboxylic acid is between 4 and 15. More preferably, the number is between 4 and 10, and most preferably between 5 and 10. A molecular weight of the carboxylic acid is preferably below 220 Dalton, in particular below 180 Dalton.

It has turned out that any further elements, in particular nitrogen, can show negative effects on the coating properties and in particular on the ball- and wedge-bonding behavior of the wire. Hence it is generally preferred that the carboxylic acid does not comprise any nitrogen atoms. Even more preferred, the coating component precursor does not contain other elements than the coating component, carbon, oxygen and hydrogen.

Generally preferred, a diameter of the wire is between 5 μm and 200 μm. Even more preferred, the invention encompasses thin bonding wires, as mentioned above.

It has surprisingly turned out that even with low concentrations of the coating component in the coating layer, a good protection of the wire against oxidation or aging is obtained. Accordingly, a total amount of the coating component in the coating layer is preferably less than 30%. More preferably, it is less than 20% and most preferably less than 10%.

Additionally or alternatively, a local amount of the coating component in the coating layer is less than 30%, wherein the amount of core main component in the coating layer is between 60% and 95%.

The amount of the component is measured by Auger depth profiling. The total amount is understood as the amount integrated over the entire depth of the wire. As a possible definition for the beginning of the bulk material of the wire core, a drop of the coating component signal below 10% of its maximum signal is used. If there is a constant signal of the coating component in the bulk material of the wire core, e.g., because of using the coating component as an additive, the respective definition of the coating layer boundary is made by subtracting this constant signal. It is noted that for other purposes, in particular the definition of an interface depth, a value of 50% of the coating component signal is used, as this allows for a sharper definition and better comparison of different samples with respect to this value.

A further aspect of the invention is a method for manufacturing a bonding wire, comprising the steps of
a. providing a core precursor of the wire with copper or silver as a core main component; and
b. depositing material to form a layer on the core precursor.

The deposited material comprises a coating component selected from the group of palladium, platinum, gold, rhodium, ruthenium, osmium and iridium, and step b is performed by depositing a film of a liquid onto the wire core precursor. The liquid contains a coating component precursor, and the deposited film is heated in order to decompose the coating component precursor into a metallic phase.

Generally, such a coating component precursor can be a suitable organic compound containing the coating component as a metal ion. One specific example would be an organic salt, e.g., an acetate, of the coating component.

Methods for direct deposition of palladium on other surfaces are known. For example, WO 98/38351 (applicant: The Whitaker Corporation, filing date: Feb. 24, 1998) describes a method of depositing palladium on metallic surfaces. It is pointed out that no electric current is used for the deposition of the metallic palladium. This document WO 98/38351 and the there described details of the deposition method are incorporated herein by reference. Examples of particular solvents are given as methanol or DMSO in WO 98/38351. For the purpose of coating bonding wires, solvents containing sulfur, like, e.g., DMSO, are generally not preferred because the sulfur could have effects on the bonding and its related structures. It is preferred that elements contained in the liquid are limited to the group core main component (copper or silver), coating component (e.g. palladium etc.), noble metals, C, H, O, and N. Other elements should be contained below contamination levels of 1%, preferably below 0.1%.

Most preferred, nitrogen is also not contained as an element in the liquid and/or is below this contamination level.

More preferred specific examples include branched carboxylic acids and specific selections therefrom as specified above.

In a specific embodiment of the present invention, this method is used to provide a coating layer on a copper wire, the coating layer comprising palladium as well as copper. Surprisingly, it has turned out that even if the liquid does not contain any copper compound, the final coating layer comprises significant amounts of copper almost over its entire depth. One attempt for explaining this surprising effect is that copper oxide, which is usually present on a surface of the copper core, might allow for dissolution of copper or copper compounds in the deposited liquid film. According to the invention, the deposition method is also applied for further combinations of a coating component with a core main component as listed above.

In order to achieve a good coating thickness and stable process conditions, the liquid preferably has a dynamic viscosity of more than 0.4 mPa*s at 20° C. More preferably, the viscosity is higher than 1.0 mPa*s, and most preferably higher than 2.0 mPa*s.

In a preferred embodiment, the heating of the deposited film is performed at temperatures higher than 150° C., in particular between 150° C. and 350° C. This provides for a quick and effective deposition of the palladium. Even more preferred, the heating is performed above 200° C., in particular between 200° C. and 300° C. Preferably, the film is still in a liquid state when the heating is started.

The deposition and/or the heating is preferably performed dynamically on the moving wire.

In a most elegant and effective method of manufacturing a bonding wire, the deposition of the film is performed after a final drawing step of the wire.

In a specifically preferred method of manufacturing a bonding wire, the bonding wire is a wire according to the invention. Hence any of the features of an inventive bonding wire can apply to an inventive method of manufacturing a bonding wire.

Generally, an inventive wire can preferably be treated in an annealing step with a temperature of at least 370° C. Even more preferred, the temperature of the annealing step is at least 430° C., wherein higher annealing temperatures can provide for higher elongation values of the wire.

Concerning further parameters for annealing, in particular thin wires need not be exposed to the annealing temperature for long. In most cases, annealing is done by pulling the wire through an annealing oven of a given length and with a defined temperature profile at a given speed. An exposure time of a thin wire to the annealing temperature is typically in the range of 0.1 second to 10 seconds.

It is pointed out that the above mentioned annealing steps can be performed before or after deposition of the coating layer, depending on the way of manufacturing the wire. In some cases it is preferred to avoid influencing the coating layer by high annealing temperatures. In such cases, the above mentioned methods, which allow for a deposition of the layer as a final manufacturing step, are preferred.

A further aspect of the invention is a system for bonding an electronic device, comprising a first bonding pad, a second bonding pad and a wire according to the invention, wherein the wire is connected to at least one of the bonding pads by ball-bonding. This combination of an inventive wire in a system is preferred due to the fact that the wire has especially beneficial properties with respect to ball bonding.

A yet further aspect of the invention is a method for connecting an electrical device, comprising the steps
a. providing a wire according to the invention;
b. bonding the wire to a first bonding pad of the device by ball bonding or wedge bonding; and
c. bonding the wire to a second bonding pad of the device by wedge bonding;
wherein steps b and c are performed without the use of a forming gas.

The wire according to the invention shows excellent properties with respect to oxidation effects. This is specifically true if a complete encapsulation of the copper core with the coating layer is present. The resulting properties allow for processing without using forming gas and hence lead to significant savings in costs and hazard precautions.

Forming gas is known in the art as a mixture of an inert gas like nitrogen with hydrogen, wherein the hydrogen content may provide for reduction reactions of oxidized wire material. In the sense of the invention, omitting forming gas means that no reactive compound like hydrogen is used. Nevertheless, use of an inert gas like nitrogen can still be advantageous.

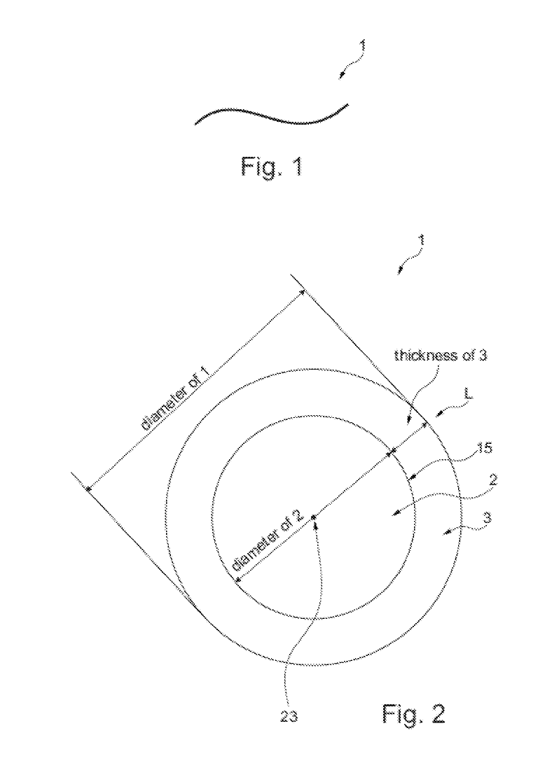

Referring to the drawings, in FIG. 1, a wire 1 is depicted. FIG. 2 shows a cross sectional view of wire 1. In the cross sectional view, a copper core 2 is in the middle of the cross sectional view. The copper core 2 is encompassed by a coating layer 3. On the limit of copper wire 2, a surface 15 of the copper core is located. On a line L through the center 23 of wire 1 the diameter of copper core 2 is shown as the end-to-end distance between the intersections of line L with the surface 15. The diameter of wire 1 is the end-to-end distance between the intersections of line L through the center 23 and the outer limit of wire 1. The thickness of coating layer 3 is also depicted.

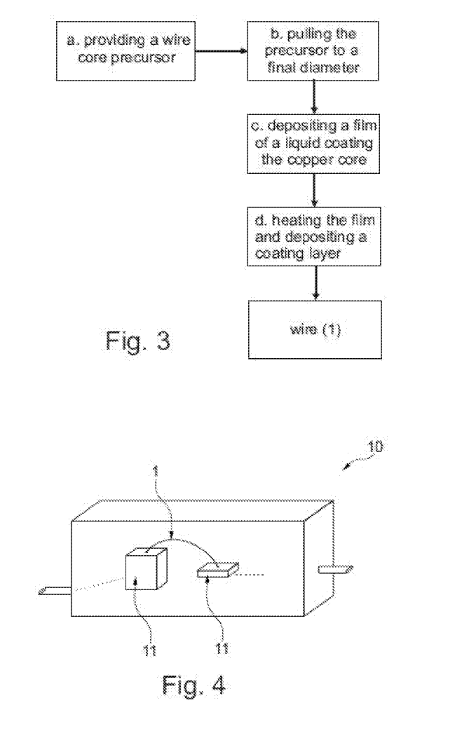

FIG. 3 is a flow chart of a process for manufacturing a wire according to an embodiment of the invention.

FIG. 4 depicts an electric comprising two elements 11 and a wire 1. The wire 1 electrically connects the two elements 11. The dashed lines mean further connections or circuitry which connect the elements 11 with external wiring of a packaging device surrounding the elements 11. The elements 11 can comprise bond pads, integrated circuits, LEDs or the like.

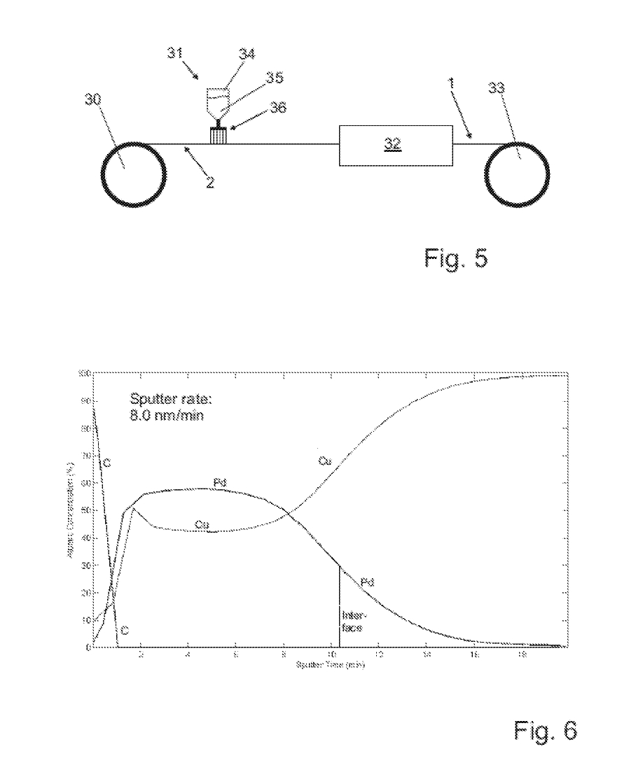

FIG. 5 is a schematic of wire coating equipment. The wire 1 is unwound from a first reel 30, dynamically pulled through a depositing device 31 and an oven 32, and finally wound onto a second reel 33. The depositing device 31 comprises a reservoir 34 containing a liquid 35, which liquid is dispensed onto the wire 1 by a dispenser 36 connected to the reservoir 34. The dispenser 36 can comprise a brush in contact with the moving wire 1 or the like.

### Test Methods

All tests and measurements were conducted at T=20° C. and a relative humidity of 50%. The wire used for testing is a thin wire with a pure copper core (4n-copper) with a coating according to the invention. The diameter of the test wire is 20 μm (=0.8 mil).

### Layer Thickness

For determining the thickness of the coating layer, the thickness of the intermediate layer, and the diameter of the core, the wire was cut perpendicular to the maximum elongation of the wire. The cut was carefully grinded and polished to avoid smearing of soft materials. A picture was recorded through a scanning electron microscope (SEM), wherein the magnification was chosen so that the full cross-section of the wire was shown.

This procedure was repeated at least 15 times. All values are provided as the arithmetic mean of the at least 15 measurements.

### Grain Size

Several measurements on the microtexture of the wire surface were made, in particular by Electron Backscattering Diffractometry (EBSD). The analysis tool used was a FE-SEM Hitachi S-4300E. The software package used for measurement and data evaluation is called TSL and is commercially available from Edax Inc., US (www.edax.com). With these measurements, size and distribution of the crystal grains of the coating layer of the wire, as well as the crystal orientation, have been determined. As the measurement and evaluation of crystal grains is presently performed by EBSD measurement, it is to be understood that a tolerance angle of 5° was set for the determination of grain boundaries. The EBSD measurements were performed directly on the untreated surface of the coating layer.

### Ball-Wedge Bonding—Parameter Definition

Bonding of a wire to a substrate plated with gold was performed at 20° C., wherein the bonding was applied to the gold surface. The device bond pad was Al-1% Si-0.5% Cu of 1 μm thickness, covered with >0.3 μm gold. After forming a first ball bond with an angle of 45° between the wire and the substrate, the wire was wedged with its second end to the substrate. The distance of the bonds between the two ends of the wire was in the range of from 5 to 20 mm. This distance was selected in order to assure the angle of 45° between the wire and the substrate. During wedge bonding, ultrasonic sound of a frequency in the range of 60-120 kHz was applied to the bondtool for 40 to 500 milliseconds.

The ball bonder equipment used was a K&S iConn with Copper Kit (S/W 8-88-4-43A-1). Testing device used was as K&S QFP 2×2 test device.

Auger Depth Profiling

The Auger depth profile of FIG. 6 is measured by following Auger-signals of the respective species (e.g. Cu, Pd, C) while sputtering the target surface at a constant sputter current density. The instrument used is a PHI 5800 ESCA.

The sputter parameters are as follows:
Sputter ion: Xenon
Sputter angle: 90°
Sputter energy: 4 keV

The depth profile is calibrated by comparison with a known standard sample. The standard sample presently used was Ta₂O₅-layers. Eventual differences in the sputter rate of the sample and the standard are corrected accordingly. This results in the sputter rate, which is 8.0 nm/min in the profile of FIG. 6. As the sputter time is measured and the sputter current density is kept constant, the time scale of the profile is easily converted to a depth scale by multiplication with the sputter rate.

### EXAMPLES

The invention is further exemplified by examples. These examples serve for exemplary elucidation of the invention and are not intended to limit the scope of the invention or the claims in any way.

The following specific examples refer to a system of copper as a core main component and palladium as a coating component in the sense of the present invention. It is generally understood that in other embodiments, these components can be substituted by the respective other preferred components according to the invention. In particular, this could be silver instead of copper for the core main component and one or more of the group of Pt, Au, Rh, Ru, Os and Ir instead of palladium for the coating component.

A quantity of copper material of at least 99.99% purity (“4N-copper”) is molten in a crucible. Then a wire core precursor of 5 mm diameter is cast from the melt.

First, the wire core precursor is extruded by means of an extrusion press, until a further core precursor of less than 1 mm diameter is obtained. This wire core precursor is then drawn in several drawing steps to form the wire core 2 with a diameter of 20 μm. The cross section of the wire core 2 is of essentially circular shape. It is to be understood that the wire diameter is not considered to be a highly exact value due to fluctuations in the shape of the cross section, a thickness of the coating layer or the like. If a wire is presently defined to have a diameter of, e.g., 20 μm, the diameter is understood to be in the range of 19.5 to 20.5 μm.

### First Example of the Invention

In a first example of an inventive wire, this wire core is wound on the first reel 30. The first reel 30 is part of the device shown in FIG. 5. The wire 1 is then unwound from the first reel 31 and wound onto the second reel 33, wherein the wire can be pulled directly by turning the second reel 33 or by a further transport drive (not shown).

On its way along the span between the reels 31, 33, the wire is first passing the depositing device 31. The reservoir 34 contains the liquid 35, which liquid is applied onto the wire 1 by means of the dispenser 36. The liquid 35 comprises isopropyl alcohol as a solvent. Palladium acetate (CH₃COO)₂Pd is dissolved in the solvent close to saturation level. The dynamic viscosity of the liquid 35 is adjusted to a value of about 2.5 mPa*s.

After dispensing the liquid onto the moving wire 1, the liquid forms a film of homogenous thickness on the surface of the wire core. This covered wire core then enters the oven 32, which is heated to 250° C. The length of the oven and the transport speed of the wire are adjusted such that the wire is exposed to the high temperature for about 5 seconds. By this exposition to the heat, the film dries out and the palladium containing substances are reduced to metallic palladium. The metallic palladium is deposited on the wire core 1 and adds to forming the coating layer 3. Further components of the coating layer are copper and carbon or carbon compounds, the latter typically collecting in an outer surface region of the coating layer.

As an alternative to providing the wire 1 from the first reel 30, the depositing device 31 and oven 32 might be provided directly in a drawing arrangement of the wire, preferably downwards of a last drawing die. It is to be understood that in the sense of the invention, there is no difference if such a direct arrangement is chosen or if the wire is provided from an intermediate reel 30 for the coating steps.

In the present example, the wire is annealed in an annealing step prior to the above described coating procedure. This annealing is performed in a known way in order to further adjust parameters like elongation, hardness, crystal structures and the like. The annealing is performed dynamically by running the wire through an annealing oven of a defined length and temperature with a defined speed. After leaving the oven, the uncoated wire is spooled on the first reel 30. It is understood that for most applications, the temperatures in such annealing step for the adjustment of, e.g., an elongation value of the wire, are much higher (typically higher than 370° C.) than the temperatures needed for the coating layer deposition. Therefore, it is usually not influencing the microstructure of the wire core in a significant way if the coating is performed as a last step.

In other embodiments of the invention, the layer deposition and the wire core annealing can be combined in a single heating step. In such an arrangement, a defined heating profile might be used which can be adjusted by special oven setups.

The resulting wire of the present embodiment showed a surface with very symmetric grains and a narrow grain size distribution. These data were collected by EBSD measurement.

TABLE 1

| Grain size circumferential direction [nm] | max | min | average |
|---|---|---|---|
| Inventive wire | 700 | 100 | 320 |
| Conventional wire | 300 | 90 | 180 |

The above Table 1 shows a comparison of the grain sizes of an inventive wire and a conventional wire. In the case of the conventional wire, the core has been electroplated with pure palladium and underwent several drawing steps afterwards.

In the longitudinal direction, the average grain size for the inventive wire is 300 nm, resulting in a value of 0.94 for a ratio of longitudinal to circumferential average grain size.

Further, a sample of the wire was cut for determination of the layer thickness by SEM as described above. An average of the measured layer thickness at different positions was calculated to be 92.6 nm.

In FIG. 6, an Auger profile of the sample wire is displayed. Material was sputtered homogenously from the wire surface in a defined area by an ion beam. Several Auger signals from different elements (displayed: carbon C, copper Cu and palladium Pd) were followed, dependent on the sputter time. The sputter rate was calibrated with a known Ta₂O₅-sample, giving a sputter rate of about 8 nm per minute. The interface of the coating layer and the core was defined as a 50% drop of the Pd-Signal from a maximum value. This gives an estimated thickness of the coating layer of about 84 nm, which is in good correlation with the average layer thickness measured by SEM.

As the wire has a diameter of 20 μm and the coating layer has a thickness of 92.6 nm, the coating layer extends from a depth of 0% of the diameter up to a depth of 0.48% of the wire diameter.

The depth profile from FIG. 6 shows that, starting with a radially outward surface of the layer, carbon is the main component at the outer region. Within the first few monolayers, the carbon signal drops sharply, while the palladium and copper signals increase. It is noted that there is nearly no palladium signal on the outermost surface, although the signal increases immediately with the start of the sputtering.

Next, the palladium signal or concentration exceeds the carbon signal at a depth of about 3 nm, marking a first change of the main component of the surface.

The copper signal reaches a local maximum at a depth of about 8 nm. The palladium and the copper signal show an almost constant value over a depth range from 10 nm to 60 nm, wherein palladium is at a level between 55% and 60% and copper is at a level of 40% to 45%, accordingly. No other elements are present at significant amounts in this region.

Then the palladium signal starts to drop, and copper becomes the main component at a depth of about 65 nm, marking a second change of the main component within the coating layer.

The average thickness of the coating layer as understood with respect to the present invention is the average thickness measured by SEM.

The Auger depth profiling as described above is used for definition of the coating layer composition and the distribution of the single components in the layer.

An outer range of the coating layer is defined as extending from 0.1% wire diameter (=20 nm) to 0.25% wire diameter (=about 50 nm). It is obvious that in this range, copper is present in an amount of more than 30%. Further, the palladium starts to drop to lower values with increasing depth within the outer range. Nevertheless, the palladium concentration drops by just a few percent within this range.

It is noted that the given depth scale of the Auger profile is sufficiently correct, as the good correlation with the average layer thickness measured by SEM confirms.

The wire sample was tested in the above described test procedures for ball bonding and wedge bonding (second bonding). Pull tests and ball shearing tests have been performed as usual testing procedures. The results have shown that the sample wire according to the invention develops a very symmetric free air ball with good reproducibility. Further, the second bond did not show any disadvantages with respect to second bonding window.

### Second Example of the Invention

In a second, more preferred example of a wire according to the invention, a copper wire is prepared as described above.

Different from the first example as described above, the coating component precursor is chosen as palladium pivalate, the palladium salt of pivalic acid, Pd((H₃C)₃C—COO)₂.

### Synthesis of Palldaium Pivalate as the Coating Component Precursor:

22.01 g Pd-acetate (48.35% Pd) are mixed with 20.4 g pivalic acid and heated and stirred at 126° C., until the resulting acetic acid is completely evaporated. This is achieved after about 35 minutes. The resulting precursor is an orange-yellow, resin-like substance.

This precursor is dissolved in tetralin (tetrahydronaphtalene) in a ratio of 1:5, obtaining the liquid to be deposited on the wire core.

Different from the first example, the coating of the wire with the liquid is performed directly after a final drawing step of the wire. This has the advantage that a fresh metal surface of the wire core is generated by the friction of the drawing die, and simultaneously the liquid is deposited onto the fresh surface.

For this purpose, a conventional drawing die, named dispenser die hereinafter, is chosen with a slightly bigger diameter (40 μm) than the final wire diameter (20 μm). This drawing die has been modified into a cup-like reservoir for the liquid, with the die opening in the center of the reservoir bottom. The wire is oriented vertically and runs through this dispenser die in downward direction.

It is understood that in this arrangement, the drawing die of the final drawing step is positioned immediately before the dispenser die. In other embodiments, the liquid could as well be directly dispensed at the drawing die of the final drawing step.

An infrared heating lamp is arranged immediately after the drawing die in order to dry off a solvent from the liquid. This drying step is performed at temperatures which do not significantly decompose organic bindings. A typical temperature is below 150° C.

After this drying step, the wire enters an annealing oven. The oven temperature is adjusted to about 400° C. In this oven, the decomposition of the coating component precursor is achieved simultaneously with an annealing of the wire core for adjustment of its crystal structure and mechanical properties (e.g., elongation). The oven has a length of 0.54 m. The wire is continuously spooled at a speed of 47 m/s.

After leaving the oven, the wire displays a silvery finish and is reeled upon a of 50 mm diameter.

This wire has undergone several bonding tests. It has also been deposited in a climate chamber at 85° C. and 85% humidity for 7 days. It was observed that no degradation of the wire's bonding and other properties appeared after this treatment.

Tests with ICP measurement showed that a total palladium share of the wire was 400 ppm, which would theoretically be equal to 11 monolayers of pure palladium.

FIG. 7 shows an Auger depth profile of the wire of the second example. Starting from the surface, carbon and copper are present, but no palladium. The palladium signal starts at a depth of about 30 nm. The palladium is then distributed in an almost Gaussian curve over a depth of more than 50 nm. A total thickness of the coating layer, defined by a 50%-drop of the Pd-signal, is roughly 90 nm.

It is obvious that the amount of palladium in the coating layer is rather small. The integral of the palladium signal over the coating layer is about 3% of the total layer material. Considering the local intensity, the maximum signal of the palladium reaches only 10%. This palladium peak intensity is reached in a region where the copper signal is increasing to about 90%.

Due to the good results, the Pd-containing layer is assumed to act as an effective oxygen-barrier, preventing oxidation of the copper. Although there appear to be significant amounts of oxide in the coating layer above the Pd-layer, this amount of oxide turned out to be harmless and even improve the wedge bonding behavior.

### Third Example of the Invention

In the third example, a pure silver bonding wire of 17 μm diameter is used as a wire core precursor. The same coating precursor and coating method as in the above second example is used. According to the slightly smaller wire diameter, a dispenser die with a smaller orifice of 35 μm is chosen. All further parameters are kept unchanged.

The Pd-coated silver wire has been tested and showed excellent bonding behavior.

The wire has been exposed to a corrosive atmosphere of 1 ppm H₂S at 75% humidity, 25° C. for 120 hours, which is a common standard test for electrical contacts and connections. The coated wire does not change its color by this treatment. It can be bonded with excellent results.

Measurements with Auger depth profiling show a similarly low Pd-concentration as in the second example.

Further tests and comparisons have been made concerning the carboxylic acid used. Additionally to pivalic acid, tests have been performed with other branched carboxylic acids. It turned out that the results were particularly good with the acids of lower carbon number, in particular dimethylbutyric acid and dimethylpentanoic acid. As a general rule, the amount of Pd in the liquid was adjusted to values between 5 wt-% and 10 wt-%.

For versatic acid 10, it turned out that the results are reasonable for lower transport speeds of the wire. For higher transport speeds, the resulting wire did not show sufficient bonding properties any more. Versatic acid 10 is also known as Neodecanoic acid and comprises 10 carbon atoms and a molecular weight of about 175.

Other solvents than tetralin can be used additionally or alternatively. One possible other solvent is butanone (methyl ethyl ketone, MEK).

It is understood that the coating component precursor in the above examples is a Pd-salt. If other metals like platinum, gold, rhodium, ruthenium, osmium and iridium are desired as a coating component, the palladium can be totally or partially substituted by one or more of these metals.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-21. (canceled)

22. A method for manufacturing a bonding wire comprising a core having a surface and a coating layer which is at least partially superimposed over the surface of the core, wherein the core comprises a core main component selected from the group consisting of copper and silver and the coating layer comprises a coating component selected from the group consisting of palladium, platinum, gold, rhodium, ruthenium, osmium and iridium, the method comprising the steps of:
a. providing a wire core precursor comprising copper or silver as a core main component; and
b. depositing a material to form a layer on the core precursor, wherein the deposited material comprises a coating component selected from palladium, platinum, gold, rhodium, ruthenium, osmium and iridium,
wherein step b is performed by depositing a film of a liquid containing a coating component precursor comprising a salt of a secondary or tertiary carboxylic acid onto the wire core precursor, and heating the deposited film to decompose the coating component precursor into a metallic phase.

23. The method of claim 22, wherein a diameter of the wire is between 5 μm and 200 μm.

24. The method of claim 22, wherein the carboxylic acid is a saturated acid.

25. The method of claim 22, wherein a number of carbon atoms in the carboxylic acid is between 4 and 15.

26. The method of claim 22, wherein the carboxylic acid comprises one or more acids selected from:
a. dimethylpropionic acid (pivalic acid),
b. dimethylbutyric acid, and
c. dimethylpentanoic acid.

27. The method of claim 22, wherein a total amount of the coating component in the coating layer is less than 30%.

28. The method of claim 22, wherein a local amount of the coating component in the coating layer is less than 30%, and wherein an amount of core main component in the coating layer is between 60% and 95%.

29. The method of claim 22, wherein the liquid has a dynamic viscosity of more than 0.4 mPa*s at 20° C.

30. The method of claim 22, wherein the heating of the deposited film is performed at temperatures higher than 150° C.

31. The method of claim 22, wherein the deposition of the film is performed after a final drawing step of the wire.

32. The method of claim 22, wherein the film of the liquid is applied onto a surface which is freshly generated while drawing the wire.

33. The method of claim 22, wherein the film of the liquid is applied at the position of a drawing die.

34. A bonding wire manufactured by the method of claim 22.
